(19) United States
(12) Patent Application Publication
(10) Pub. No.: US 2025/0095958 A1
(43) Pub. Date: Mar. 20, 2025

(54) CONOSCOPIC WAFER ORIENTATION FOR ION IMPLANTATION

(71) Applicant: Applied Materials, Inc., Santa Clara, CA (US)

(72) Inventors: Frank SINCLAIR, Hartland, ME (US); Timothy THOMAS, Portland, OR (US); Jinxin FU, Fremont, CA (US); Micha NIXON, Sitriya (IL)

(73) Assignee: Applied Materials, Inc., Santa Clara, CA (US)

(21) Appl. No.: 18/794,582

(22) Filed: Aug. 5, 2024

Related U.S. Application Data
(60) Provisional application No. 63/538,668, filed on Sep. 15, 2023.

(51) Int. Cl. H01J 37/304; H01J 37/147; H01J 37/22; H01J 37/244; H01J 37/317

(52) U.S. Cl. CPC H01J 37/3045; H01J 37/1472; H01J 37/226; H01J 37/244; H01J 37/3171; H01J 2237/2007; H01J 2237/20207; H01J 2237/20214; H01J 2237/2441; H01J 2237/2446

(57) ABSTRACT

An ion implanter may include an ion source to generate an ion beam. The ion implanter may include a set of beamline components to direct the ion beam to a substrate along a beam axis, as well as a process chamber to house the substrate to receive the ion beam. The ion implanter may include a conoscopy system, comprising: an illumination source to direct light to a substrate position; a first polarizer, having a first polarization axis, disposed between the illumination source and the substrate position; a second polarizer, the second polarizer being disposed to receive the light after passing through the substrate position. The conoscopy system may include a lens, to receive the light after passing through the substrate position, and a detector, to detect the light after passing through the lens.

### RELATED APPLICATIONS

This application claims priority to U.S. provisional patent application Ser. No. 63/538,668, filed Sep. 15, 2023, entitled CONOSCOPIC WAFER ORIENTATION FOR ION IMPLANTATION, the contents of which application are incorporated by reference herein in their entirety.

### FIELD

The present embodiments relate to ion implantation, and more particularly to substrate orientation in ion implanters.

### BACKGROUND

Silicon Carbide has emerged as one of the most promising materials for high voltage, high power switching applications. The SiC compound is readily formed in many different crystal structures, each with their own crystallographic and electronic properties. The most popular SiC material is the “4H” polytype, which structure has hexagonal symmetry and a pattern of hexagonal layers that repeats every 4 layers: ABCBABCBABC. . . . This crystal belongs to the P6₃mc or C⁴₆ᵥ space group. In a hexagonal crystal, the crystalline structure is characterized by a set of axes where an a-axis and a b-axis are equal in dimension to one another and extend perpendicularly to a c-axis, which axis has a different dimension than the a-axis and b-axis. To form monocrystalline 4H SiC wafers, SiC crystalline boules are typically grown at very high temperatures by vapor phase deposition. In order to maintain the polytype structure and minimize defects, the growing surface may be tilted at 4° to the c-axis. Since the growth forms a roughly cylindrical boule whose length is much shorter than the boule diameter, to cut the maximum number of wafers from the SiC boule, the wafers are also cut approximately parallel to the growth surface.

The manufacture of high voltage devices entails the creation of regions several microns thick that are depleted of any charge carriers and thus able to withstand high voltages without significant current. One of the best methods to achieve these regions is through deep ion implantation. For a given crystalline substrate, the depth of an ion implant is principally determined by the energy and mass of the ions, but can be significantly modified by the alignment of the ion trajectories with the crystal structure of the substrate. In SiC substrates these alignment effects have a much greater impact than for silicon substrates, because of the potential energy due to the alternating silicon and carbon atoms in the structure and the lower symmetry of the crystal. In some examples, the implantation depth of ions may vary up to 100% or more, depending upon the orientation of the silicon carbide crystal. Also, the amount of crystal damage caused may be reduced significantly by aligning the ion beam with the crystal direction. Thus, in the processing of silicon carbide devices, knowledge of the crystal orientation becomes extremely important.

With respect to these and other considerations the present embodiments are provided.

### SUMMARY

In one embodiment, an ion implanter is provided. The ion implanter may include an ion source to generate an ion beam. The ion implanter may include a set of beamline components to direct the ion beam to a substrate along a beam axis, as well as a process chamber to house the substrate to receive the ion beam. The ion implanter may include a conoscopy system, comprising: an illumination source to direct light to a substrate position; a first polarizer, having a first polarization axis, disposed between the illumination source and the substrate position; a second polarizer, the second polarizer being disposed to receive the light after passing through the substrate position. The conoscopy system may include a lens, to receive the light after passing through the substrate position, and a detector, to detect the light after passing through the lens.

In another embodiment, a method of implanting a substrate may include generating an ion beam in an ion implanter, directing the ion beam to a substrate along a beam trajectory, determining an offset angle for the substrate using a conoscopy system within the ion implanter, and tilting the substrate at the offset angle when the ion beam impinges upon the substrate.

### BRIEF DESCRIPTION OF DRAWINGS

FIG. 1 depicts an exemplary ion implantation system in accordance with embodiments of the present disclosure;

FIG. 2 shows an example of a conoscopy system, according to an embodiment of the disclosure;

FIG. 3 depicts details of an exemplary ion implantation system in accordance with other embodiments of the present disclosure;

FIG. 4 and FIG. 5 together show an example of conoscopy imaging to determine substrate alignment;

FIG. 6 shows another example of conoscopy imaging to determine substrate alignment;

FIG. 7A is a simulated conoscopy pattern for a 4H SiC illuminated with 550 nm wavelength radiation;

FIG. 7B is a simulated conoscopy pattern for a 4H SiC illuminated with 380 nm wavelength radiation;

FIG. 7C is a simulated conoscopy pattern for a 4H SiC illuminated with 266 nm wavelength radiation;

FIG. 8 depicts an exemplary process flow; and

FIG. 9 depicts another exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to apparatus and techniques for improved substrate ion implantation. The present embodiments employ novel ion implantation systems, also referred to herein as ion implanters, which implanters incorporate a conoscopy system to provide in-situ accurate substrate orientation. In various embodiment, the substrate orientation may be performed so as to align the crystallographic structure of the substrate to present a so-called channeling orientation with respect to an ion beam that is used to implant the substrate. In so doing, the implant profile and in particular, the implant depth of the ions of the ion beam may be substantially increased for a given ion energy and given substrate.

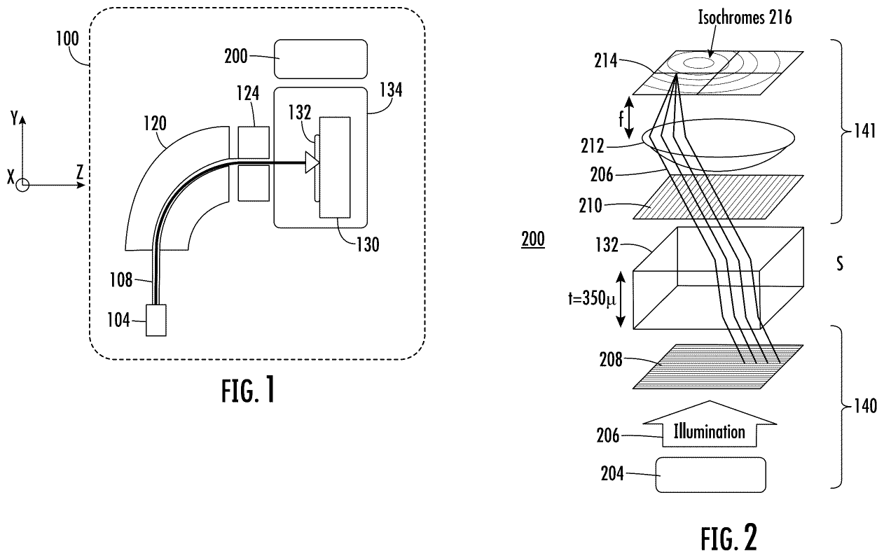

Referring now to FIG. 1, an exemplary system in accordance with the present disclosure is shown. The ion implantation system 100 represents a beamline ion implanter containing, among other components, an ion source 104 for producing an ion beam 108, and a series of beam-line components, disposed between the ion source 104 and a substrate 132. The ion source 104 may comprise a chamber for receiving a flow of gas and generating ions therein. The ion source 104 may also comprise a power source and an extraction electrode assembly disposed near the chamber. The beam-line components may include, for example, a mass analyzer 120, and other beamline components, as known in the art. These other beamline components are represented by downstream components 124, and may include acceleration or deceleration stages, a collimator, a mass resolving slit, a scanner, energy filter, and/or other suitable downstream beamline components (not shown), to accelerate the ion beam 108, decelerate the ion beam 108, shape the ion beam 108, scan the ion beam 108, and so forth.

The ion beam 108 may be directed toward a substrate 132 mounted on a substrate holder 130, and disposed within a process chamber, which process chamber may be part of an end station 134, or adjacent to the end station 134. As appreciated, the substrate may be moved using a control mechanism in one or more dimensions and type of motions (e.g., translate, rotate, and tilt).

In various embodiments, different species may be used as the source and/or the additional material. Examples of the source and/or additional material may include atomic or molecular species containing boron (B), carbon (C), nitrogen (N), oxygen (O), germanium (Ge), phosphorus (P), aluminum (Al), arsenic (As), silicon (Si), helium (He), neon (Ne), argon (Ar), krypton (Kr), nitrogen (N), hydrogen (H), fluorine (F), and chlorine (Cl). Those of ordinary skill in the art will recognize the above listed species are non-limiting, and other atomic or molecular species may also be used. Depending on the application(s), the species may be used as the dopants or the additional material. In particular, one species used as the dopants in one application may be used as the additional material in another application, or vice-versa.

Although non-limiting, the ion source 104 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art.

The ion source 104 may generate the ion beam 108 for implanting into substrate 132. In various embodiments, the ion beam 108 (in cross-section) may have a targeted shape, such as a spot beam or ribbon beam, as known in the art. In the Cartesian coordinate system shown, the direction of propagation of the ion beam 108 may be represented as parallel to the Z-axis, while the actual trajectories of ions with the ion beam 108 may vary. In order to implant into the substrate 132, the ion beam 108 may be accelerated to acquire a target energy by establishing a voltage (potential) difference between the ion source 104 and the substrate 132, or by other means of acceleration such as used in linear accelerators.

As further shown in FIG. 1, the ion implantation system 100 may include apparatus to perform conoscopic measurement of the substrate 132, which apparatus is depicted as conoscopy system 200. In some embodiments, the conoscopy system 200 may be partially or wholly located in a part of the ion implantation system 100 that is separate from the end station 134, while in other embodiments, the conoscopy system may be integrated at least partially, within the end station 134. Moreover, the conoscopy system may be located outside of a process chamber that receives an ion beam, but is located within other locations in the end station 134. For example, according to some non-limiting embodiments, the conoscopy system 200 may be located in an existing load lock of the ion implantation system 100, may be located in an orienter than orients the substrate 132, or within a process chamber portion of the end station 134, or in an optical system that is affixed to a portion of the ion implantation system 100.

FIG. 2 shows an example of a variant of the conoscopy system 200, according to an embodiment of the disclosure. In FIG. 2, an arrangement of the conoscopy system 200 is shown, including a lower part 140 designed to produce suitable illumination of the substrate 132 with a converging beam of polarized light, and an upper part 141 designed to produce a conoscopic image. As will be understood, the substrate 132 may be manipulated while in the conoscopy system 200 in order to perform measurements that indicate the crystallographic orientation of the substrate 132. As shown, the conoscopy system 200 may include an illumination source 204, which source may be a visible light source, or an ultraviolet (UV) light source, according to some non-limiting embodiments. The conoscopy system 200 may further include a first polarizer 208, having a first polarization axis, which axis may be deemed to lie along a Y-axis, for the purposes of illustration. The first polarizer 208 is disposed between the illumination source 204 and the substrate position S. As such, radiation, such as a beam of radiation, or other shape of radiation generated from illumination source 204, referred to as light 206, that passes into the substrate 132, when located at the substrate position S, will first pass through the first polarizer 208. The conoscopy system 200 may further include a second polarizer 210, having a second polarization axis that is oriented at a right angle with respect to the first polarization axis, such as along an X-axis that is orthogonal to the Y-axis. As shown, the second polarizer 210 is disposed to receive the light 206 after passing through the substrate position S. The conoscopy system 200 may further include a lens 212, disposed to receive the light 206 after passing through the second polarizer 210.

The conoscopy system 200 may further include a two dimensional detector, shown as detector 214, to detect the light 206 after passing through the lens 212. The detector 214 may be any suitable detector to detect a pattern of polarized and focused light as known in the art. In some embodiments, the detector 214 may be a solid state detector, such as a CMOS detector, a charge coupled device (CCD), and so forth.

In some embodiments, the detector 214 may form a two-dimensional image or pattern suitable for interpretation by a computer algorithm. In this conoscopic approach, the imaging lens (lens 212) is positioned so that an image sensor (see detector 214) is in the back focal plane of the lens and thus each point in the image corresponds to one angle of propagation of the light through the substrate 132. Said another way, the “camera” formed by the lens and the image sensor is focused at infinity so that the image is not a conventional image of the sample, but is a conoscopic image of the angles of light in the crystal.

Advantageously, the conoscopy system 200 may be employed to accurately determine crystallographic orientation of a substrate, especially for a monocrystalline substrate that is optically birefringent. As an example, the 4H polytype of SiC, also referred to herein as “4H SiC” crystallizes in the P6₃mc space group, representing a hexagonal crystal structure, and is strongly optically birefringent (uniaxial). The optical birefringence is reflected in a significantly lower index of refraction for light rays that travel along the c-axis of the crystal (the “ordinary” direction), than the index of refraction for rays travelling at right angles to this axis, with an electric vector along the c-axis (the “extraordinary” direction.)

For light rays having electric vectors at intermediate angles, light entering the 4h SiC crystal will split into two wave fronts that will then propagate through the crystal at different wavelengths, recombining when the wavefronts emerge back into air (or vacuum). Since the two components will have a phase shift when recombined, this effect will rotate the plane of polarization. This rotation of the polarization can easily be detected by the use of a pair of crossed polaroid filters, as embodied in the first polarizer 208 and second polarizer 210. Thus, just light where the direction of polarization has been rotated will pass through the second polarizer 210, while light that has not had the plane of polarization rotated will be absorbed by the second polarizer and those parts of the image will appear as a black cross (an isogyre) in the conoscopic image. One other condition may occur when the plane of polarization has been rotated by exactly 180°, or an integral product of 180°, in which case the second polarizer will again block the light and produce a series of concentric dark circles (isochromes).

In the embodiments detailed herein, the figures and description are most suitable for the case of monitoring orientation in a uniaxial crystal with no strain. In a biaxial crystal, where the indicatrix has three different axes, the conoscopic images produced are more complicated: the isogyres appear as a single dark stripe across the field of view, and the isochromes become ellipsoidal. In crystals with strain, the images are further distorted by piezooptical effects. In other embodiments of the disclosure, the operation of the conoscopic system disclosed herein can be extended to these more complicated situations by interpreting the image and matching it to a model that includes these complicating effects.

The conoscopy system 200 may thus be effectively used to examine a birefringent substrate such as 4H SiC, or other known birefringent material. Note that according to various embodiments, some components of the conoscopy system 200 may be arranged similarly to known conoscopy systems, and may include microscopy components to provide modest magnification, with the objective lens focused at infinity rather than at a sample position. In this manner, every position of an image 216, formed on the detector 214 may correspond to the direction of the light 206, rather than a position on the sample. Thus, the components of the conoscopy system 200 may be employed to identify the direction of the optical axis of a substrate 132, such as 4H SiC, with respect to any suitable geometric reference system, such as a Cartesian coordinate system used to handle and orient substrates in the ion implantation system 100. Once the orientation of the optical axis of the substrate 132 is known, the substrate 132 may be suitably positioned for implantation in the end station 134, such as being place in an orientation to promote ion channeling along the c-axis of the substrate 132.

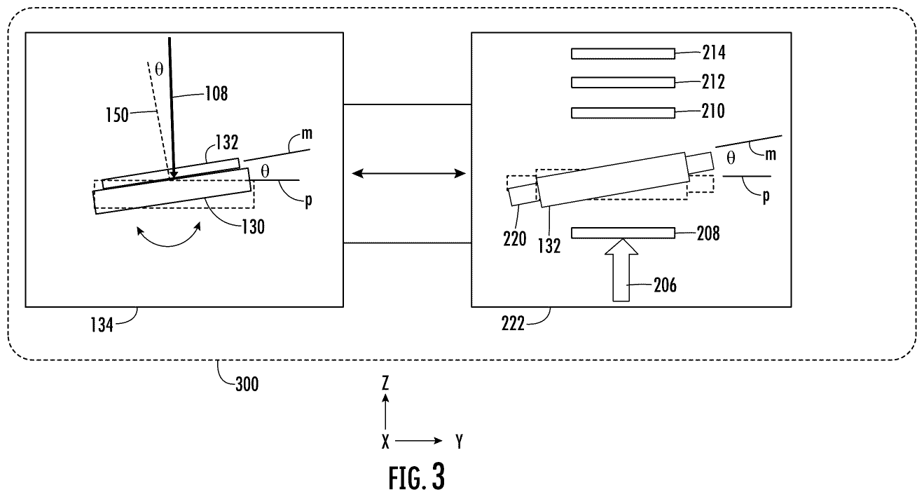

FIG. 3 depicts details of an exemplary ion implantation system in accordance with other embodiments of the present disclosure. The ion implantation system 300 may include known components of an ion implanter, such as those components detailed above with respect to FIG. 1. In the view of FIG. 3, just the end station 134 and conoscopy system 200 are shown.

In the embodiment shown in FIG. 3, the conoscopy system 200 is located in a part of the ion implantation system, denoted as a chamber 222, that is separate from the end station 134. However, as noted above, in other embodiments, the conoscopy system 200 may be integrated, at least partially, within the end station 134.

In this embodiment, the conoscopy system 200 may further include a substrate stage 220, to hold the substrate 132 at the substrate position S. In an untilted configuration, represented by the dashed lines, a main plane of the substrate 132, such as a plane corresponding to a top surface of the substrate 132, may be used to define a reference plane P. For sake of illustration, the reference plane P may correspond to the X-Y plane of the Cartesian coordinate system shown. The substrate stage 220 may include two adjustable angle components to tilt and rotate the substrate 132 so that the main plane m defines a non-zero angle with respect to reference plane P. The tilt angle may be shown as θ in FIG. 3, while rotating the substrate around the normal 150 to the substrate by a twist angle φ. By tilting and twisting the substrate stage 220 so as to vary a value of θ the detector 214 may be monitored to determine an orientation, also referred to herein as an offset orientation. This offset orientation may correspond to the orientation of substrate 132 that provides a maximum channeling of ions of ion beam 108 when the substrate 132 is transferred to end station 134 and ion implantation is commenced. Thus, by determining the optimum values of φ and θ in the conoscopy system 200, the substrate 132 may be oriented with this same optimum value of φ and θ when located in the end station, so as to promote channeling of the ion beam 108.

Note that the tilt angle θ may also be equivalent to an incidence angle of the ion beam 108, as defined with respect to the normal 150. Thus, because the ion beam 108 may form a trajectory that is aligned along a normal to the when oriented a suitable value of θ, with respect to reference plane P, when the substrate 132 is oriented at a proper value of θ, the ion beam 108 will impinge upon the surface of the substrate 132 at a trajectory that defines the same value of with respect to the normal 150. Since the c-axis of the crystal forming the substrate 132 may be aligned at the angle θ with respect to normal 150, the ion beam 108 may enter into the substrate 132 parallel to the C-axis and thus along a so-called channeling direction, assuming a proper twist angle alignment.

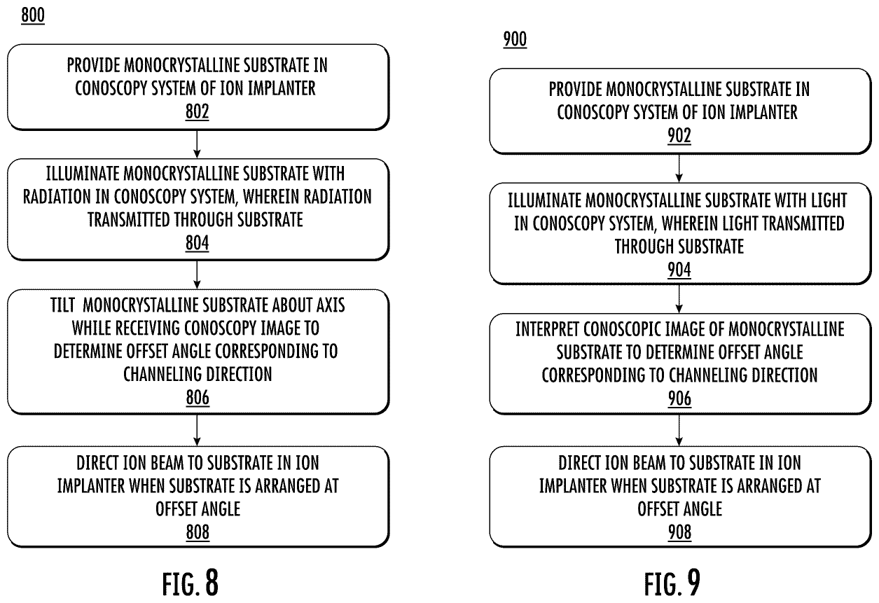

According to different embodiments of the disclosure, several modes of operation are possible. For a crystal having uncertain optical properties, it may be advantageous to analyze the image of isogyres and isochromes for different tilt angles θ at one location and then by observing the relative shift of the image measure the refractive index of the material, as well as the inclination of the optical axis to the normal of the surface. For a crystal of known optical properties and with a well aligned optical system, it is possible to determine the tilt angle θ and twist angle o by locating the isogyres and isochromes in the image plane with no motion of the crystal required, as shown in FIG. 9, described in more detail below. For a crystal having significant inhomogeneities or strain, it may be advantageous to make the measurement at several different positions (x,y) to explore possible variations in the direction of the optical axis across the wafer, so that an average angle could be used for the ion implantation. If the angle variation across the wafer is significant it may be advantageous to vary the direction of the ion beam in some systematic way as a function of x and y across the face of the wafer (meaning the main surface of a substrate) to compensate for wafer crystal distortion.

In another embodiment, one mode of operation that may be particularly effective and impose a minimum added delay in wafer processing is described in the following scenario. Note that existing practice for wafer handling before a given implant procedure, is to use a separate station in the vacuum chamber (separate from an endstation where wafer implantation takes place) to identify the twist angle of the notch or flat that wafer manufacturers use to indicate the crystal alignment. This station already has a rotating support for the wafer and a light sensor that produces a signal at the notch or flat on the edge of the wafer. In this new embodiment, this same station may be equipped with the conoscopic inspection system of the present embodiments, where the system can image the interference pattern at, e.g., four rotation angles by sighting through the edge of the wafer. Given knowledge of the refractive index and the birefringence of the wafer material, each image may be interpreted to produce the desired tilt and twist angles for the implant, which tilt/twist information may then be fed forward to the implant endstation controller to allow the positioning of the wafer for implant. The use of several independent positions on the wafer for the inspection will provide an accuracy check, as well as allowing for the detection of wafers with significant strain and variation of crystal axes.

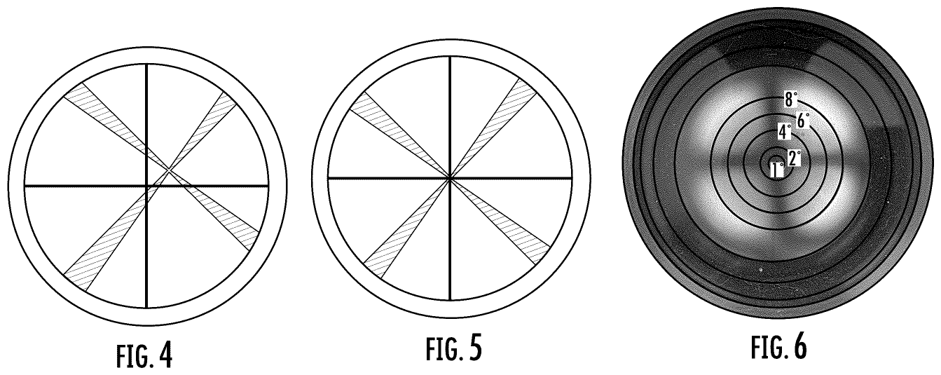

FIG. 4 and FIG. 5 shows an example of conoscopy imaging to determine substrate alignment. In FIG. 4, a microscopic image is presented representing a possible conoscopic pattern. The image of FIG. 4 may represent an image plane where every point in the image plane corresponds to an angle of propagation through the crystal being measured. The dark triangular regions may represent isogyres that are composed of dark bands where just one wave propagates through the crystal. In FIG. 4, the isogyres are not convergent at the center of the cross pattern, indicating misalignment of the crystal, while in FIG. 5, the isogyres tips do converge at the center of the cross pattern, forming a symmetrical pattern, indicating alignment.

FIG. 6 shows another example of conoscopy imaging to determine substrate alignment. In this example, the crystal being measured is a ruby crystal (corundum crystal structure), which structure is a hexagonal (or trigonal) type of crystalline lattice. The isogyres are generally aligned to the center of the image, indicating alignment, with some distortion in the isogyre, likely caused by twinning or strain in the ruby sample.

Referring again to FIG. 3, an advantage afforded by the ion implantation system 300 is that a substrate, such as a monocrystalline substrate that exhibits birefringence, can be readily tilted to present a substrate surface that is oriented to improve channeling just before implantation commences, using an in-situ conoscopic system. Note that for some materials, and especially for 4H SiC, the implantation depth of ions may be very sensitive to substrate orientation, such that small changes in substrate orientation may substantially change the implantation depth. Moreover, as noted previously, the substrate surface (main plane) of such 4H SiC substrates may oriented at several degrees off axis so that the c-axis is not oriented at a normal to substrate surface. Thus, when an offcut 4H SiC substrate is placed in an implanter at a nominally horizontal orientation, where the Z-axis is parallel to the ion beam, and the main plane of the substrate is parallel to the X-Y plane, the ion beam will enter the substrate along a beam trajectory that is not parallel to the c-axis of the 4H SiC crystalline lattice. The ion beam will therefore not enter the 4H SiC lattice along a channeling direction, thus reducing the potential implant depth of implanting ions. Moreover, the exact amount of offcut of the substrate surface with respect to the c-axis may not accurately be known a priori. Therefore, the timely and accurate tilting of the substrate 132 to align the c-axis of the crystalline lattice with the trajectory of the ion beam 108 may be harnessed to great advantage by the ion implantation system 300.

To emphasize the above points, and by way of reference, the inventors note that the effect of substrate offset angle on ion depth profile for aluminum ion implantation into 4H SiC has previously been reported. The results for aluminum ion implantation showed, at 8 or 9 degrees of tilt, the penetration of the ions is approximately half as much as for ions aligned with the c-axis, corresponding to the channeling orientation. Accordingly, the expectation is: misorientation of the c-axis of 4H SiC wafer of even a fraction of a degree may substantially reduce ion penetration into the 4H SiC wafer.

While in principle a conoscopy system may be used to properly orient a substrate in an ion implanter to improve channeling, a drawback of the application of a conoscopy system for measuring substrates such as 4HSiC is the fact that the accuracy of the determination of ideal offset angle to orient the substrate with c-axis alignment will decrease with decreasing thickness of a substrate. For example, practical thicknesses of substrates used for power semiconductor application may be in the range of several hundred micrometers. At this thickness, the resulting conoscopic images may provide less accuracy for determining c-axis alignment than is provided with other techniques, such as X-ray diffraction.

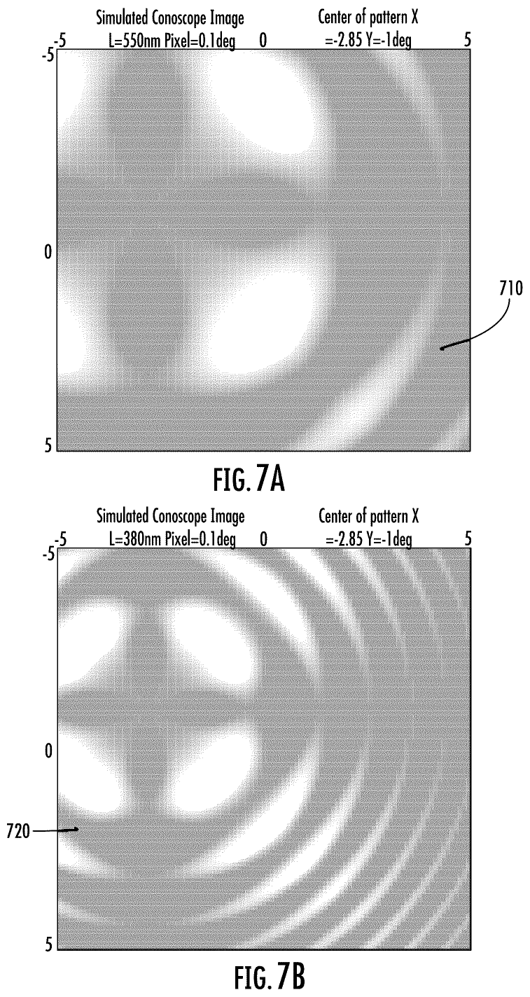

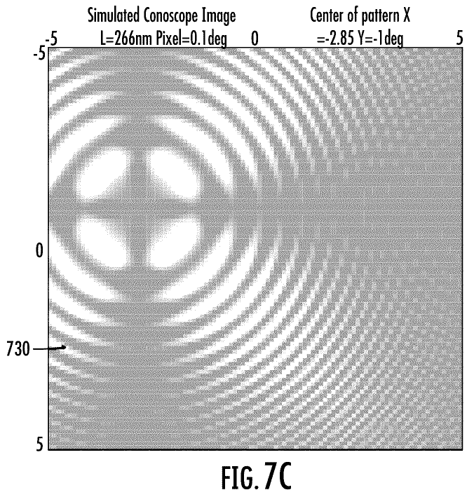

To address this issue, the present inventors have determined that decreasing the wavelength of incident radiation used to perform the conoscopic alignment procedures as outlined above may provide substantial improvement in measurement accuracy. To illustrate the improvement possible by reducing wavelength, FIG. 7A is a simulated conoscopy pattern for a 4H SiC illuminated with 550 nm wavelength radiation; FIG. 7B is a simulated conoscopy pattern for a 4H SiC illuminated with 380 nm wavelength radiation; and FIG. 7C is a simulated conoscopy pattern for a 4H SiC illuminated with 266 nm wavelength radiation. In particular, each of the patterns of these figures represents a pixelated simulated image that employs a simple model using 0.1° pixels distributed over ±5°. Note that a full frame 35 mm SLR camera with 200 mm lens has ±5° field of view, so the model of these figures is within practical implementation. However, in the sample of FIG. 7A, with 500 nm wavelength, location of the center of the pattern 710 may be difficult, at least to a desired accuracy less than 0.1 degrees.

Turning to FIG. 7B, at the relatively shorter wavelength of 380 nm, the frequency of the pattern 720 increases for two reasons: the refractive index and birefringence of the SiC crystalline material increases, and the number of wavelengths within a SiC wafer increases. In this example, with proper image processing, location of the center of the pattern 720 to within one pixel (meaning to within 0.1 degree) may be possible.

Turning to FIG. 7C, at 266 nm (UV wavelengths), the pattern 730 is sufficiently detailed wherein location of the center and orientation of a crystal to within <0.1 degrees is readily achievable. However, the transmissivity of SiC substrates at this wavelength may limit use of this approach and the cost of the instrumentation needed may be too high. In view of the above, operation at violet or near UV wavelengths in the range of (375 nm to 450 nm) may be useful for a conoscopy system of the present embodiments.

FIG. 8 depicts an exemplary process flow 800. At block 802, a monocrystalline substrate is provided in a conoscopy system of an ion implanter. In one example, the monocrystalline substrate may be a birefringent substrate, such as 4H SiC. At block 804, the monocrystalline substrate is illuminated with radiation in a conoscopy system, wherein the radiation is transmitted through the substrate. In some non-limiting embodiments, the wavelength of the radiation may lie between 550 nm and 375 nm.

At block 806, the monocrystalline substrate is tilted about an axis to provide different orientations of the substrate, while a conoscopy image is received at the different orientations. In so doing, an offset angle may be determined for the substrate that corresponds to a channeling direction for ions being implanted into the substrate. Said differently, the offset angle may correspond to an offcut angle of a substrate with respect to a c-axis of the crystalline lattice of the substrate.

At block 808, an ion beam is directed to the substrate in the ion implanter while the substrate is arranged at the offset angle.

FIG. 9 depicts another exemplary process flow 900. At block 902, a monocrystalline substrate is provided in a conoscopy system of an ion implanter. In one example, the monocrystalline substrate may be a birefringent substrate, such as 4H SiC. At block 904, the monocrystalline substrate is illuminated with light in a conoscopy system, wherein the light is transmitted through the substrate. In some non-limiting embodiments, the wavelength of the radiation may lie between 550 nm and 375 nm.

At block 906, a conoscopic image of the monocrystalline substrate, based upon the operation of block 904, is interpreted to determine an offset angle corresponding to a channeling direction of the monocrystalline substrate.

At block 908, an ion beam is directed to the monocrystalline substrate in the ion implanter while the substrate is arranged at the offset angle.

One advantage of the present embodiments is the ability to accurately determine crystallographic orientation of a substrate, especially for a monocrystalline substrate that is optically birefringent. This determination allows the proper orientation to be set for a given substrate during implantation, such as a tilt orientation to promote ion channeling and therefore deeper implants. Another advance of the present embodiments is the ability to use conoscopy to measure local angular variation across a substrate. In this manner, the angle with respect to an implanting ion beam can be varied as a function of position on a substrate, in order to promote the desired implantation result, such as uniform implant depth.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. An ion implanter, comprising:
an ion source to generate an ion beam;
a set of beamline components to direct the ion beam to a substrate along a beam axis;
a process chamber to house the substrate to receive the ion beam; and
a conoscopy system, disposed within the ion implanter, and comprising:
an illumination source to direct light to a substrate position;
a first polarizer, having a first polarization axis, and being disposed between the illumination source and the substrate position;
a second polarizer, the second polarizer being disposed to receive the light after passing through the substrate position;
a lens, disposed to receive the light after passing through the substrate position; and
a detector, to detect the light after passing through the lens.

2. The ion implanter of claim 1, wherein the conoscopy system further comprises:
a substrate stage, the substrate stage to hold the substrate at the substrate position, wherein a main plane of the substrate defines a reference plane, in an untilted configuration, and wherein the substrate stage includes at least a tilt component, to rotate the substrate wherein the main plane of the substrate defines a non-zero angle with respect to the reference plane.

3. The ion implanter of claim 2, wherein the radiation forms a symmetrical pattern at the detector when the non-zero angle defines an offset angle wherein a c-axis of the substrate is aligned along a normal to the reference plane.

4. The ion implanter of claim 3, wherein the substrate presents a channeling orientation to the ion beam when the substrate stage is tilted at the offset angle.

5. The ion implanter of claim 3, wherein the detector is configured to determine a value of the offset angle to within 0.1 degrees.

6. The ion implanter of claim 3,
wherein the conoscopy system is disposed outside of the process chamber of the ion implanter,
wherein the process chamber further comprises a substrate holder, having a rotation component to rotate the substrate within the process chamber, wherein the main plane of the substrate is tilted at the offset angle,
wherein the ion beam impinges on the substrate along a beam trajectory defining an incidence angle with respect to a normal to the main plane of the substrate, equivalent to the offset angle, when the substrate stage is tilted at the offset angle.

7. The ion implanter of claim 3, wherein the substrate stage of the conoscopy system is disposed within the process chamber of the ion implanter, wherein the ion beam impinges on the substrate along a beam trajectory defining an incidence angle with respect to a normal to the main plane of the substrate that is equivalent to the offset angle, when the substrate stage is tilted at the offset angle.

8. The ion implanter of claim 1, wherein the substrate is 4H—SiC.

9. The ion implanter of claim 1, wherein the light comprises radiation having a wavelength between 375 nm and 450 nm.

10. The ion implanter of claim 1, wherein the detector is a solid state detector.

11. A method of implanting a substrate, comprising:
generating an ion beam in an ion implanter;
directing the ion beam to a substrate along a beam trajectory;
determining an offset angle for the substrate using a conoscopy system within the ion implanter, and
tilting the substrate at the offset angle when the ion beam impinges upon the substrate.

12. The method of claim 11, the conoscopy system comprising:
an illumination source to direct light to a substrate position;
a first polarizer, having a first polarization axis, and being disposed between the illumination source and the substrate position;
a second polarizer, the second polarizer being disposed to receive the light after passing through the substrate position;
a lens, disposed to receive the light after passing through the substrate position; and
a detector, to detect the light after passing through the lens.

13. The method of claim 12, wherein the illumination passes through the substrate when the substrate is disposed at the substrate position.

14. The method of claim 12, wherein the radiation forms a symmetrical pattern at the detector when the offset angle is such that a c-axis of the substrate is aligned along the beam trajectory.

15. The method of claim 14, wherein the substrate presents a channeling orientation to the ion beam when the substrate is tilted at the offset angle.

16. The method of claim 14, wherein the detector is configured to determine a value of the offset angle to within 0.1 degrees.

17. The method of claim 12,
wherein the ion beam impinges upon the substrate in a process chamber, wherein the conoscopy system is disposed outside of the process chamber, the method further comprising:
transferring the substrate from the conoscopy system to a substrate holder in the process chamber; and
rotating the substrate on the substrate holder wherein the main plane of the substrate is tilted at the offset angle,
wherein the ion beam impinges on the substrate along a beam trajectory defining an incidence angle with respect to a normal to the main plane of the substrate, equivalent to the offset angle.

18. The method of claim 12, wherein the substrate stage of the conoscopy system is disposed within the process chamber of the ion implanter, wherein the ion beam impinges on the substrate along a beam trajectory defining an incidence angle with respect to a normal to the main plane of the substrate that is equivalent to the offset angle, when the substrate is tilted at the offset angle.

19. The method of claim 11, wherein the substrate is 4H—SiC.

20. The method of claim 11, wherein the light comprises radiation having a wavelength between 375 nm and 450 nm.
